(19) United States
(12) Patent Application Publication
(10) Pub. No.: US 2018/0312958 A1
(43) Pub. Date: Nov. 1, 2018

(54) VAPOR DEPOSITION APPARATUS AND METHOD FOR MANUFACTURING FILM

(71) Applicants: BOE Technology Group Co., Ltd., Beijing (CN); Hefei Xinsheng Optoelectronics Technology Co., Ltd., Hefei (CN)

(72) Inventors: Donghui Zhang, Beijing (CN); Guodong Liu, Beijing (CN); Xiaoye Ma, Beijing (CN); Rui Ma, Beijing (CN); Zixuan Wang, Beijing (CN)

(21) Appl. No.: 15/862,898

(22) Filed: Jan. 5, 2018

(30) Foreign Application Priority Data
Apr. 27, 2017 (CN) 201710287202.2

(51) Int. Cl. C23C 14/22; H01M 4/04; C23C 16/455; C23C 16/46; C23C 16/52

(52) U.S. Cl. CPC C23C 14/226; H01M 4/0428; C23C 16/52; C23C 16/46; C23C 16/455

(57) ABSTRACT

The present disclosure relates to a vapor deposition apparatus and a method for manufacturing films. The vapor deposition apparatus includes a platform, a heater and a controller. The controller is configured to control the heater to heat a film formation region of a substrate on the platform, thereby enabling a temperature of the film formation region to reach a film formation temperature of the vapor deposition.

### CROSS-REFERENCE TO RELATED APPLICATION

This application is based on and claims the priority of the Chinese patent application No. 201710287202.2 filed on Apr. 27, 2017, which is incorporated herein by reference in its entirety.

### TECHNICAL FIELD

The present disclosure relates to the field of manufacturing display products, and in particular to a vapor deposition apparatus and a method for manufacturing films.

### BACKGROUND

In the process of manufacturing display substrates, a chemical deposition process is usually used to form a function layer on a substrate.

The chemical deposition process is carried out in a high temperature. In the chemical deposition process in the related art, reaction gas is directly heated to a high temperature, and the reaction gas of high temperature contacts the substrate and is gradually deposited on the substrate to form a film structure.

However, when the reaction gas is heated to the high temperature, the reaction gas may be deposited on the whole surface of the substrate. In most cases, a function layer only needs to be formed on some regions of the substrate, and thus an amount of reaction material gas used in the chemical deposition process in the related art is relatively high, resulting in high production costs.

In addition, when the reaction material gas is heated, heat dissipation often causes the reaction material gas to be of different temperatures, resulting in the heating effect not being ideal.

### SUMMARY

An object of the present disclosure is to solve the problem that the amount of reaction material gas used in the chemical deposition process in the related art is relatively high.

In order to achieve the above object, according to one aspect, one embodiment of the present disclosure provides a vapor deposition apparatus including a platform, at least one heater and a controller. The controller is configured to control the heater to heat a film formation region of a substrate on the platform, thereby enabling a temperature of the region to reach a film formation temperature of the vapor deposition.

Further, the apparatus further includes a vapor deposition chamber. The platform is in the vapor deposition chamber.

Further, the substrate is provided with a conductive pattern, the film formation region includes a region where the conductive pattern is located. The heater includes a first power supply device and an electromagnetic induction coil; the controller is configured to control the first power supply device to apply an alternating current to the electromagnetic induction coil, thereby directly heating the conductive pattern with electromagnetic energy.

Further, the controller is further configured to control the electromagnetic induction coil to heat the conductive pattern by controlling a frequency of the alternating current applied by the first power supply device to the electromagnetic induction coil.

Further, the platform is disposed at a bottom of the vapor deposition chamber, a top surface of the platform is configured to carry the substrate, and the electromagnetic induction coil is disposed outside of the vapor deposition chamber under the platform, and the platform and the vapor deposition chamber are made of electrolyte materials.

Further, the heater includes a second power supply device and a heating resistor; the controller is configured to control the second power supply device to apply a direct current to the heating resistor, thereby controlling the heating resistor to heat the substrate in such a manner that the film formation region of the substrate is heated in a heat conduction manner.

Further, the apparatus further includes a flat heat-conducting material layer. The heat resistor is disposed at a surface of the platform where the substrate is placed, and is covered by the flat heat-conducting material layer; and the platform carries the substrate via the flat heat-conducting material layer.

Further, the surface of the platform where the substrate is placed, is divided into a plurality of independent heating regions, and there is at least one heating resistor in each heating region; each heating resistor is configured to heat the flat heat-conducting material layer in the heating region corresponding to the each heating resistor.

Further, the controller is configured to control the second power supply device to apply a current to some of the heating resistors.

Further, the apparatus further includes a temperature sensor which is configured to detect a temperature of the film formation region and output temperature information of the film formation region. The controller is further configured to receive the above temperature information, and control the heater to heat the film formation region at a constant temperature according to the temperature information.

Further, the temperature sensor includes an infrared temperature sensor that is disposed on the vapor deposition chamber and above the platform.

Further, the apparatus further includes an introduction device disposed in the vapor deposition chamber. The introduction device is configured to introduce a reaction material gas into the vapor deposition chamber.

Further, the apparatus further includes an air exhaust device; wherein the air exhaust device is mounted on the vapor deposition chamber, and is configured to exhaust the reaction material gas from the vapor deposition chamber.

Further, the introduction device and the air exhaust device are disposed at two opposite sides of the vapor deposition chamber.

Further, the apparatus further includes a material recovery device; wherein the material recovery device is connected with the air exhaust device, and is configured to recycle the reaction material gas exhausted by the air exhaust device.

According to another aspect, one embodiment of the present disclosure provides a method for manufacturing a film, including: using the above vapor deposition apparatus to form a film on a film formation region.

Further, the film formation region is a region where a gate electrode is located, and the film is a semiconductor thin film.

### BRIEF DESCRIPTION OF THE DRAWINGS

FIG. 1 is a schematic view of a vapor deposition apparatus according to an embodiment of the present disclosure;

FIG. 2 is a schematic view of a vapor deposition apparatus according to another embodiment of the present disclosure; and

FIG. 3 is a schematic view of a vapor deposition apparatus according to still another embodiment of the present disclosure.

### DETAILED DESCRIPTION

In order to make the objects, the technical solutions and the advantages of the present disclosure more apparent, the present invention will be described hereinafter in conjunction with the drawings and embodiments.

With respect to the problem that the amount of material gas used in the chemical deposition process in the related art is relatively high, the present disclosure provides a solution.

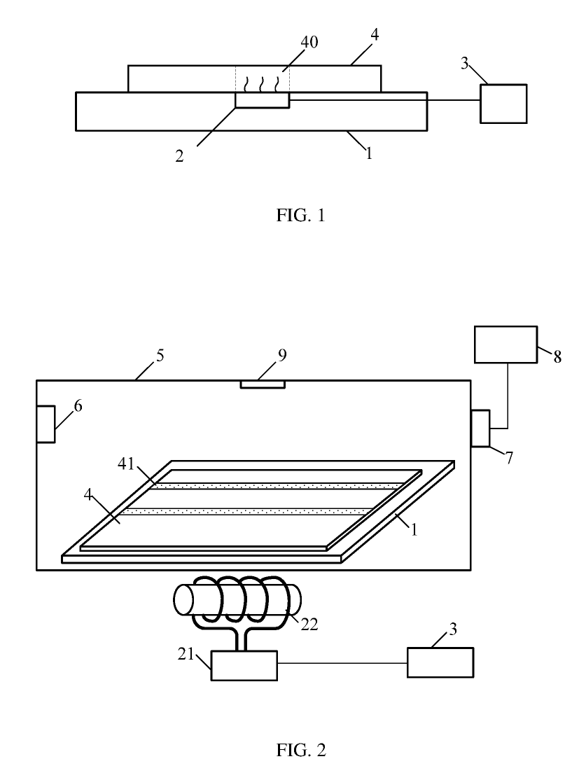

According to one aspect, as shown in FIG. 1, a vapor deposition apparatus according to an embodiment of the present disclosure includes a platform 1, at least one heater 2 and a controller 3. The controller 3 is to control the heater 2 to heat a film formation region 40 of a substrate 4 on the platform 1, thereby enabling a temperature of the film formation region 40 to reach a film formation temperature of the vapor deposition.

As can be seen from the above content, the vapor deposition apparatus of one embodiment of the present disclosure can accurately heat the film formation region 40 of the substrate, and a material gas can react at the film formation region 40, thereby forming the film. Thus, the material gas can be effectively used, and then avoid unnecessary waste of resources. In addition, since the vapor deposition apparatus of one embodiment of the present disclosure directly heats the film formation region 40 of the substrate, heating efficiency and heating effect are significantly higher than those of the method for heating material gas in the related art. As a result, the yield of products is also improved.

The vapor deposition apparatus of one embodiment of the present disclosure will be described hereinafter in details in combination with practical applications.

On the basis of the vapor deposition apparatus shown in FIG. 1, the vapor deposition apparatus shown in FIG. 2 further includes a vapor deposition chamber 5, an air exhaust device 7 and a material recovery device 8.

The vapor deposition chamber 5 is provided with an introduction device 6. The introduction device 6 is to introduce a reaction material gas into the vapor deposition chamber 5. The air exhaust device 7 is mounted on the vapor deposition chamber 5, and is to exhaust the reaction material gas from the vapor deposition chamber 5. The material recovery device 8 is connected with the air exhaust device 7, and is to recycle the reaction material gas exhausted by the air exhaust device 7.

The platform 1 is disposed in the vapor deposition chamber 5, so that vapor deposition reaction can be carried out in a sealed environment provided in the vapor deposition chamber 5.

As examples, in one embodiment of the present disclosure, the film formation region of the substrate may be heated in two modes.

One heating mode is an electromagnetic heating mode. In one embodiment of the present disclosure, as shown in FIG. 2, a conductive pattern 41 is disposed on the substrate 4, and the film formation region includes a region where the conductive pattern 41 is located. Accordingly, the heater 2 includes a first power supply device 21 and an electromagnetic induction coil 22.

In one embodiment, the controller 3 is to control the first power supply device 21 to apply alternating current to the electromagnetic induction coil 22.

When an alternating current is applied to the electromagnetic induction coil 22, the electromagnetic induction coil 22 can generate an alternating magnetic field. Magnetic lines of the alternating magnetic field cut the conductive pattern 41, thereby generating an eddy current in the conductive pattern 41. Then the eddy current causes atoms in the conductive pattern 41 to move irregularly at high speed to produce heat energy, thereby enabling a temperature of the conductive pattern 41 to reach a film formation temperature. When the reaction material gas contacts the region where the conductive pattern 41 is located, related chemical reactions occurs, thereby forming a thin film adjacent the conductive pattern 41.

Since a temperature of a region where a non-conductive pattern is located of the substrate 4, does not reach the film formation temperature, then no thin film will formed at the region where the non-conductive pattern is located of the substrate 4. As a result, the reaction material gas is saved.

Specifically, the controller 3 may control a frequency of the alternating current applied by the first power supply device 21 to the electromagnetic induction coil 22. Then, the controller 3 can control the electromagnetic induction coil 22 to heat the conductive pattern 41.

After many practices, it is found that when the frequency of the alternating current applied to the electromagnetic induction coil 22 is controlled to be in a range of from 44 MHz to 55 Mhz, preferably 50 MHz, more efficient and stable heating effect can be obtained.

In addition, in one embodiment, the controller 3 may also control magnitudes of current and/or voltage applied by the first power supply device 21 to the electromagnetic induction coil 22. Then, the controller 3 can control the electromagnetic induction coil 22 to heat the conductive pattern 41 to a desired temperature.

Apparently, the greater the current and/or voltage of the alternating current, the greater the heating temperature of the conductive pattern 41; the smaller the current and/or voltage of the alternating current, the smaller the heating temperature of the conductive pattern 41. In actual application, different film materials are corresponding to different film formation temperatures, thus magnitudes of current and/or voltage may be set according to actual situations and will not be elaborated herein.

In addition, on the basis of the above, optionally, the electromagnetic induction coil 22 may be disposed at an outside of the vapor deposition chamber 5, thereby preventing the electromagnetic induction coil 22 from being corroded by the reaction material gas.

Specifically, the platform 1 may be disposed at a bottom of the vapor deposition chamber 5, a top surface of the platform 1 is used to carry the substrate 4, and the electromagnetic induction coil 22 is disposed under the platform 1. The platform 1 and the vapor deposition chamber 5 may be made of electrolyte materials, so that the magnetic field of the electromagnetic induction coil 22 can effectively pass through the platform 1 and the vapor deposition chamber 5 and then directly heat the conductive pattern 41.

In actual application, the conductive pattern 41 may be an electrode, a signal line or other pattern on a display substrate, and the electromagnetic heating mode can be used to form a thin film which covers the conductive pattern or is on the region where the conductive pattern is located.

As can be seen from the above description, the electromagnetic heating mode directly heats the conductive pattern 41. Although the electromagnetic induction coil 22 is spaced from the conductive pattern 41 by a certain distance, heat conduction is not required. Thus, the heating efficiency is high, and then heating time required by chemical vapor deposition can be effectively reduced.

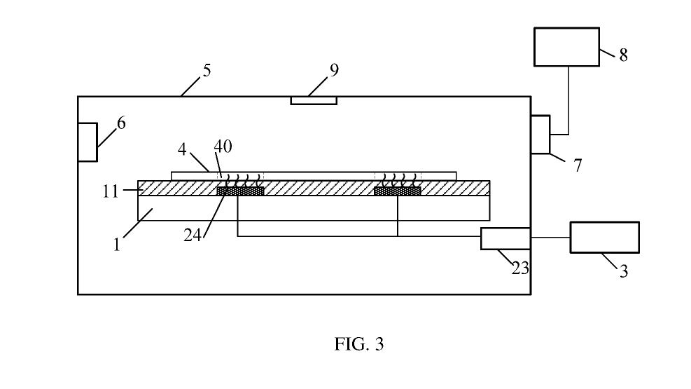

Another heating mode is a resistance heating mode. In one embodiment, as shown in FIG. 3, the heater 2 may include a second power supply device 23 and a heating resistor 24.

The controller 3 is to control the second power supply device 23 to apply a direct current to the heating resistor 24, thereby controlling the heating resistor 24 to heat the substrate 4. Then, the film formation region of the substrate 4 is heated in a heat conduction manner.

Apparently, the resistance heating mode is different from the electromagnetic heating mode, and the resistance heating mode is to improve the temperature of the film formation region in the heat conduction manner. Thus, the closer the heating resistor is to the film formation region, the higher the heating efficiency.

Therefore, in one embodiment, the heat resistor 24 may be disposed at a surface of the platform 1 where the substrate is placed, and then is covered by a flat heat-conducting material layer 11. The platform 1 stably carries the substrate 4 via the flat heat-conducting material layer 11.

When a current is applied to the heating resistor 24, heat generated by the heating resistor 24 can be conducted to the film formation region 40 of the substrate 4 by mean means of the flat heat-conducting material layer 11.

As an example, in one embodiment, a carrying surface of the platform 1 may be divided into a plurality of independent heating regions, and there is at least one heating resistor 24 in each heating region. Each heating resistor 24 is to heat the flat heat-conducting material layer 11 in the heating region corresponding to the each heating resistor 24.

In actual application, substrates of different types may have different film forming positions, and the controller 3 may control the second power supply device 23 to apply a current to only the heating resistor 24 in the heating region which is required to be heated, thereby effectively using the reaction material gas.

In addition, optionally, as shown in FIG. 2 or FIG. 3, the vapor deposition apparatus of one embodiment may further include a temperature sensor 9. The temperature sensor 9 is to detect a temperature of the film formation region, and output temperature information of the film formation region.

Accordingly, the controller 3 can receive the above temperature information, and control the heater to the film formation region at a constant temperature according to the temperature information, thereby ensuring the film quality.

For example, with respect to the electromagnetic heating mode, the controller 3 may control magnitudes of current, voltage and frequency of the alternating current applied to the electromagnetic induction coil 22, thereby keeping the film formation region at a constant temperature. With respect to the resistance heating mode, the controller 3 may control the magnitude of current applied to the heating resistor 24, thereby keeping the film formation region at a constant temperature.

In actual application, the temperature sensor 9 may be an infrared temperature sensor which can obtain the temperature information of the film formation region at a certain distance away from the film formation region.

The forgoing descriptions are only optional embodiments of the vapor deposition apparatus of the present disclosure. It should be understood that the above descriptions are merely exemplary, are not intended to limit the scope of the present disclosure, and numerous improvements and substitutions may further be made by those skilled in the art without being departing from the principle of the present disclosure, and those improvements and substitutions shall fall into the scope of protection of the present disclosure. For example, positions of the electromagnetic induction coil 22 and the heating resistor 24 can be adjusted, i.e., when the electromagnetic induction coil 22 is properly sealed up, the electromagnetic induction coil 22 may be disposed in the vapor deposition chamber 5; the connection between the controller 3 and the first power supply device 21 or the second power supply device 23 may be a wireless connection or a wired connection.

According to another aspect, one embodiment of the present disclosure further provides a method for manufacturing films, which includes using the above vapor deposition apparatus to form a film on a film formation region of the substrate.

Apparently, based on the above vapor deposition apparatus, the method for manufacturing films can effectively use the material gas to form films and shorten film formation time, thereby significantly reducing production cost and significantly improving production efficiency, providing high practical value for manufacturers.

In actual application, the method may be used to form a semiconductor thin film of monocrystalline silicon (the material of the semiconductor thin film is not limited to monocrystalline silicon) on a gate electrode of an array substrate (i.e., the film formation region is a region where the gate electrode is located), and the reaction material gas may include SiH4. It should be noted that in a specific manufacturing process, different film materials require different film formation temperatures. For example, the above semiconductor thin film of monocrystalline silicon, it is better to control the temperature of the film formation region at about 300 degrees centigrade. Since the heating effect depends on the specific material of the film, the temperature required for the film formation region will not be elaborated herein.

The above are merely the preferred embodiments of the present disclosure and shall not be used to limit the scope of the present disclosure. It should be noted that, a person skilled in the art may make improvements and modifications without departing from the principle of the present disclosure, and these improvements and modifications shall also fall within the scope of the present disclosure.

What is claimed is:

1. A vapor deposition apparatus comprising:
a platform;
at least one heater; and
a controller;
wherein the controller is configured to control the heater to heat a film formation region of a substrate on the platform, thereby enabling a temperature of the film formation region to reach a film formation temperature of the vapor deposition.

2. The apparatus of claim 1, further comprising: a vapor deposition chamber;
wherein the platform is in the vapor deposition chamber.

3. The apparatus of claim 2, wherein:
the substrate is provided with a conductive pattern;
the film formation region includes a region where the conductive pattern is located;
the heater includes a first power supply device and an electromagnetic induction coil; and
the controller is configured to control the first power supply device to apply an alternating current to the electromagnetic induction coil, thereby directly heating the conductive pattern with electromagnetic energy.

4. The apparatus of claim 3, wherein the controller is further configured to control the electromagnetic induction coil to heat the conductive pattern by controlling a frequency of the alternating current applied by the first power supply device to the electromagnetic induction coil.

5. The apparatus of claim 3, wherein the platform is disposed at a bottom of the vapor deposition chamber, a top surface of the platform is configured to carry the substrate, and the electromagnetic induction coil is disposed outside of the vapor deposition chamber under the platform, and the platform and the vapor deposition chamber are made of electrolyte materials.

6. The apparatus of claim 2, wherein:
the heater comprises a second power supply device and a heating resistor; and
the controller is configured to control the second power supply device to apply a direct current to the heating resistor, thereby controlling the heating resistor to heat the substrate in such a manner that the film formation region of the substrate is heated in a heat conduction manner.

7. The apparatus of claim 6, further comprising a flat heat-conducting material layer;
wherein the heat resistor is disposed at a surface of the platform where the substrate is placed, and is covered by the flat heat-conducting material layer; and
wherein the platform carries the substrate via the flat heat-conducting material layer.

8. The apparatus of claim 7, wherein:
the surface of the platform where the substrate is placed is divided into a plurality of independent heating regions, and there is at least one heating resistor in each heating region; and
each heating resistor is configured to heat the flat heat-conducting material layer in the heating region corresponding to each respective heating resistor.

9. The apparatus of claim 8, wherein the controller is configured to control the second power supply device to apply a current to some of the heating resistors.

10. The apparatus of claim 1, further comprising a temperature sensor which is configured to detect a temperature of the film formation region and output temperature information of the film formation region;
wherein the controller is further configured to receive the temperature information, and control the heater to heat the film formation region at a constant temperature according to the temperature information.

11. The apparatus of claim 10, wherein the temperature sensor includes an infrared temperature sensor that is disposed on the vapor deposition chamber and above the platform.

12. The apparatus of claim 2, further comprising an introduction device disposed in the vapor deposition chamber;
wherein the introduction device is configured to introduce a reaction material gas into the vapor deposition chamber.

13. The apparatus of claim 12, further comprising an air exhaust device; wherein the air exhaust device is mounted on the vapor deposition chamber, and is configured to exhaust the reaction material gas from the vapor deposition chamber.

14. The apparatus of claim 13, wherein the introduction device and the air exhaust device are disposed at two opposite sides of the vapor deposition chamber.

15. The apparatus of claim 13, further comprising a material recovery device;
wherein the material recovery device is connected with the air exhaust device, and is configured to recycle the reaction material gas exhausted by the air exhaust device.

16. A method for manufacturing a film, comprising: using the vapor deposition apparatus of claim 1 to form the film on a film formation region of a substrate.

17. The method of claim 16, wherein the film formation region is a region where a gate electrode is located, and the film is a semiconductor thin film.
